(19) United States
(12) Patent Application Publication
(10) Pub. No.: US 2009/0320923 A1
(43) Pub. Date: Dec. 31, 2009

(54) PHOTOVOLTAIC CONCENTRATING APPARATUS

(75) Inventors: Hwa Yuh SHIN, Lungtan (TW); Hwen Fen Hong, Lungtan (TW); Chieh Cheng, Lungtan (TW); Hung Sheng Chiu, Lungtan (TW); Yen Cheng Tzeng, Lungtan (TW)

Correspondence Address: EGBERT LAW OFFICES, 412 MAIN STREET, 7TH FLOOR, HOUSTON, TX, 77002, US

(73) Assignee: ATOMIC ENERGY COUNCIL - INSTITUTE OF NUCLEAR ENERGY RESEARCH, Lungtan (TW)

(21) Appl. No.: 12/547,289

(22) Filed: Aug. 25, 2009

Related U.S. Application Data
(63) Continuation of application No. 11/326,808, filed on Jan. 6, 2006.

(30) Foreign Application Priority Data
Oct. 28, 2005 (TW) 094137771

(51) Int. Cl. H01L 31/00

(52) U.S. Cl. 136/259

(57) ABSTRACT

The present invention discloses a photovoltaic concentrating apparatus comprising a supporter and at least one collecting unit positioned on the supporter. The supporter includes a plurality of beams having at least one groove positioned on a side surface of the beam. The collecting unit includes a Fresnel lens and a solar cell module. The Fresnel lens is positioned on the supporter via a loading frame with a wing capable of engaging with the groove of the beam, and the solar cell module is positioned on the supporter via a substrate. Particularly, the supporter includes an upper frame for supporting the Fresnel lens and a bottom frame for supporting the solar cell module.

### RELATED U.S. APPLICATIONS

This present application is a continuation application of U.S. patent application Ser. No. 11/326,808, filed on Jan. 6, 2006, being entitled “PHOTOVOLTAIC CONCENTRATING APPARATUS”.

### STATEMENT REGARDING FEDERALLY SPONSORED RESEARCH OR DEVELOPMENT

Not applicable.

### REFERENCE TO MICROFICHE APPENDIX

Not applicable.

### BACKGROUND OF THE INVENTION

1. Field of the Invention

The present invention generally relates to a graphical user interface. In particular, the present invention relates to a window display system for performing automatic adjustment of windows and a method thereof.

2. Description of Related Art Including Information Disclosed Under 37 CFR 1.97 and 37 CFR 1.98

As industry is experiencing rapid growth, petroleum exhaust and the discharge of greenhouse gases from the use of petroleum are drawing more and more attention. Nowadays, researchers try to find alternative energy sources to achieve a stable energy supply. One such alternative energy source is solar cells, which use the photoelectric effect to transform solar energy into electrical energy without generating polluting gases or greenhouse gases such as those produced by conventional energy sources. Particularly, solar cells can supply stable and safe electrical energy to decrease the use of petroleum.

A. W. Bett et al. disclose a solar energy collecting module consisting of a plurality of collecting units, including a Fresnel lens, a glass frame, a glass substrate and a heat sink (See FLATCON™ and FLASHCON™ CONCEPTS FOR HIGH CONCENTRATION PV, Presented at the 19th European Photovoltaic Solar Energy Conference, 7-11 Jun. 2004, Paris). Particularly, each element of the collecting unit is made of glass, which is heavy and inconvenient to assemble. Further, the Fresnel lens and the glass substrate are assembled on the glass frame, and the glass frame must be redesigned whenever the position of the Fresnel lens or the glass substrate is changed. In short, the solar energy collecting module disclosed by A. W. Bett et al. is too heavy for easy assembly, lacks flexibility for design changes, and therefore cannot be widely used.

### BRIEF SUMMARY OF THE INVENTION

The objective of the present invention is to provide a photovoltaic concentrating apparatus, which possesses flexibility for changing architecture and low manufacturing cost.

In order to achieve the above-mentioned objective and avoid the problems of the prior art, one embodiment of the present invention discloses a photovoltaic concentrating apparatus comprising a supporter and at least one collecting unit positioned on the supporter. The supporter includes a plurality of beams having at least one groove positioned on a side surface of each beam. The collecting unit includes a Fresnel lens positioned on the supporter via a loading frame and a solar cell module positioned on the supporter via a plate. Further, the supporter comprises an upper frame for supporting the Fresnel lens and a bottom frame for supporting the solar cell module.

The solar cell module comprises a dielectric substrate positioned on the plate, a solar cell positioned on the upper surface of the dielectric substrate, a protection diode positioned on the upper surface of the dielectric substrate, a condenser configured to condense light beams from the Fresnel lens to the solar cell, and a heat sink positioned on the back surface of the dielectric substrate. Preferably, the supporter is made of aluminum or aluminum-containing alloy and the beam includes at least one hollow interior to reduce the weight of the supporter. In addition, the surface of the supporter is preferably blasted, anodized, or electroplated.

The supporter may comprise a corner member having a plurality of openings for connecting two perpendicular beams, a nut positioned in the groove of the beam, and a bolt capable of fixing the corner member on the beam, wherein the two perpendicular beams can be assembled by the screwing of the bolt and the nut via the opening of the corner member. In addition, the supporter may comprise a nut positioned in a first beam, a fixture having an opening positioned in a second beam perpendicular to the first beam, and a bolt capable of fixing the first beam and the second beam, wherein the first beam and the second beam can be assembled by the screwing of the bolt and the nut via the opening of the fixture.

The prior art uses frames made of glass, which is too heavy to be assembled conveniently and lacks flexibility for design changes. Conversely, the present supporter is preferably made of aluminum or aluminum-containing alloy and the beam includes at least one hollow interior, and therefore can decrease the weight of the photovoltaic concentrating apparatus dramatically. In addition, the beam of the supporter is grooved, which allows the Fresnel lens and the solar cell module to be assembled at a random position on the beam, and therefore a designer or user can randomly change the number and position of the Fresnel lens and the solar cell module, i.e. the present photovoltaic concentrating apparatus possesses flexibility for changing architecture randomly.

### BRIEF DESCRIPTION OF THE SEVERAL VIEWS OF THE DRAWINGS

The objectives and advantages of the present invention will become apparent upon reading the following description and upon reference to the accompanying drawings.

FIG. 1 to FIG. 4 illustrate perspective views and an elevation view of a photovoltaic concentrating apparatus according to one embodiment of the present invention.

FIG. 5 and FIG. 6 illustrate exploded perspective views of an assembly of a supporter according to one embodiment of the present invention.

### DETAILED DESCRIPTION OF THE INVENTION

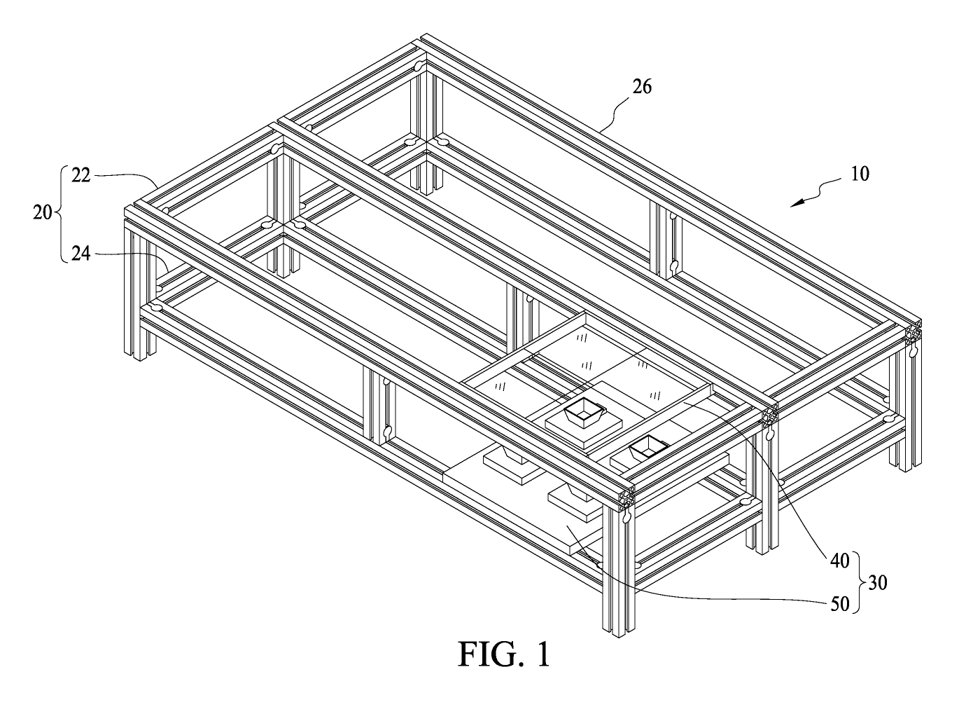

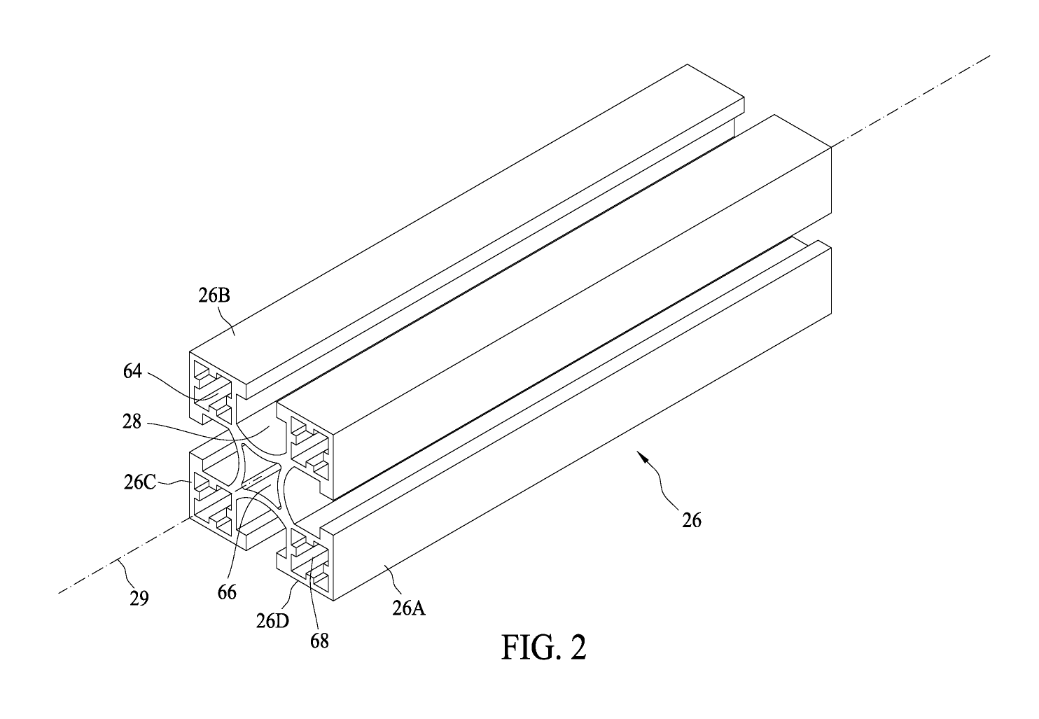

FIG. 1 to FIG. 4 illustrate a photovoltaic concentrating apparatus 10 according to one embodiment of the present invention. The photovoltaic concentrating apparatus 10 comprises a supporter 20 and at least one collecting unit 30 positioned on the supporter 20. The collecting unit 30 includes a Fresnel lens 40 positioned on the supporter 20 via a loading frame 42 and a solar cell module 50 positioned on the supporter 20 via a plate 52, wherein the loading frame 42 comprises a wing 44 which can be inserted into the groove 28 of the beam 26. Particularly, the supporter 20 comprises an upper frame 22 for supporting the Fresnel lens 40 and a bottom frame 24 for supporting the solar cell module 50. The supporter 20 includes a plurality of beams 26 having at least one groove 28 positioned on a side surface of the beam 26. Preferably, the supporter 20 is made of aluminum or aluminum-containing alloy and the beam 26 includes at least one hollow interior 64 to reduce weight, as shown in FIG. 2.

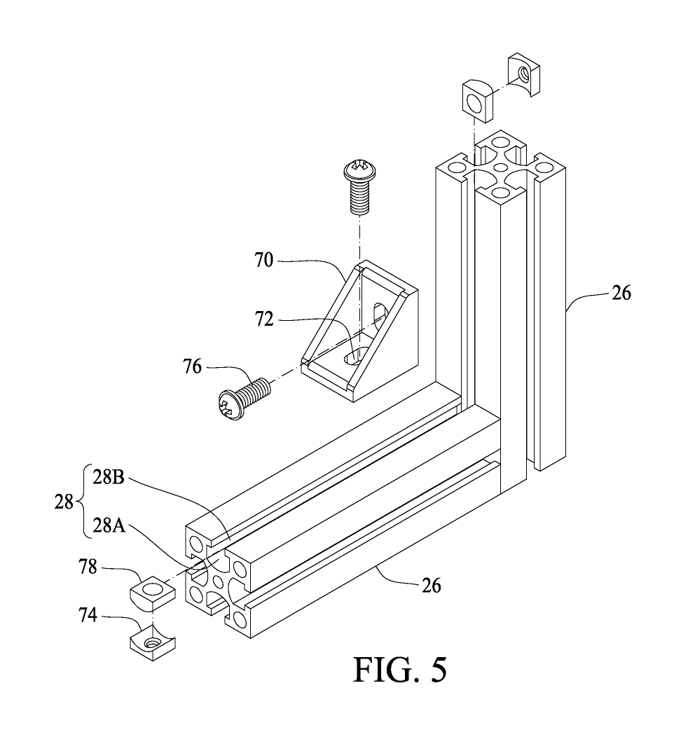

The beam 26 has four side surfaces 26A-26D, each of four side surfaces 26A-26D has the groove 28, and the grooves 28 of the four side surfaces 26A-26D are symmetric along a central line 29. The grooves 28 have the same cross-section. The beam includes a central hole 66 and four corner holes 68, and the corner holes 68 have the same cross-section. The corner holes 68 are symmetric along the central line 29. The central hole is disposed among the grooves 28. Each groove 28 is sandwiched between two corner holes 68. In one embodiment of the present invention, the cross-section of the central hole 66 is different from the cross-section of the corner holes 68, as shown in FIG. 2. In another embodiment of the present invention, the cross-section of the central hole 66 is the same as the cross-section of the corner holes 68, as shown in FIG. 5.

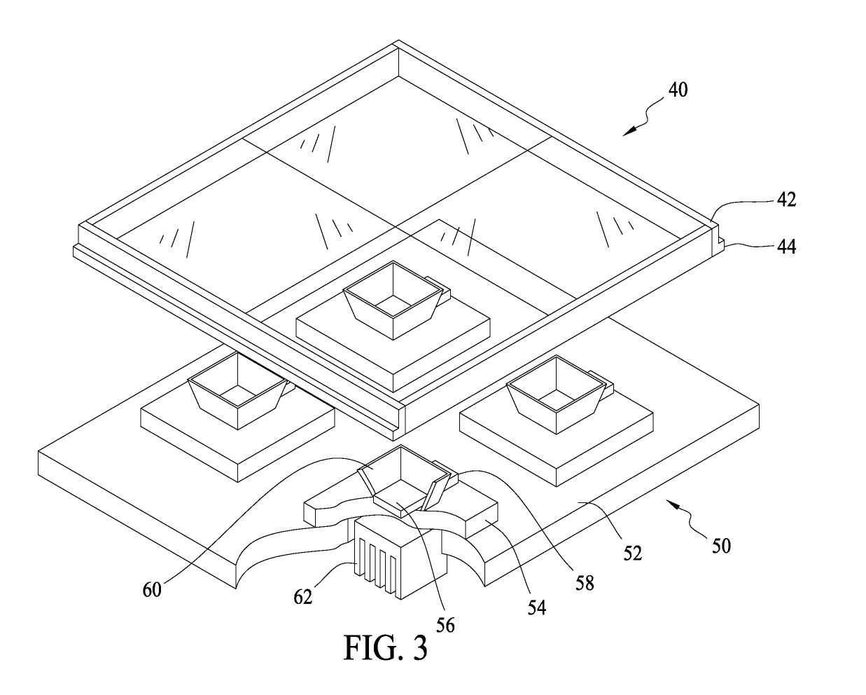

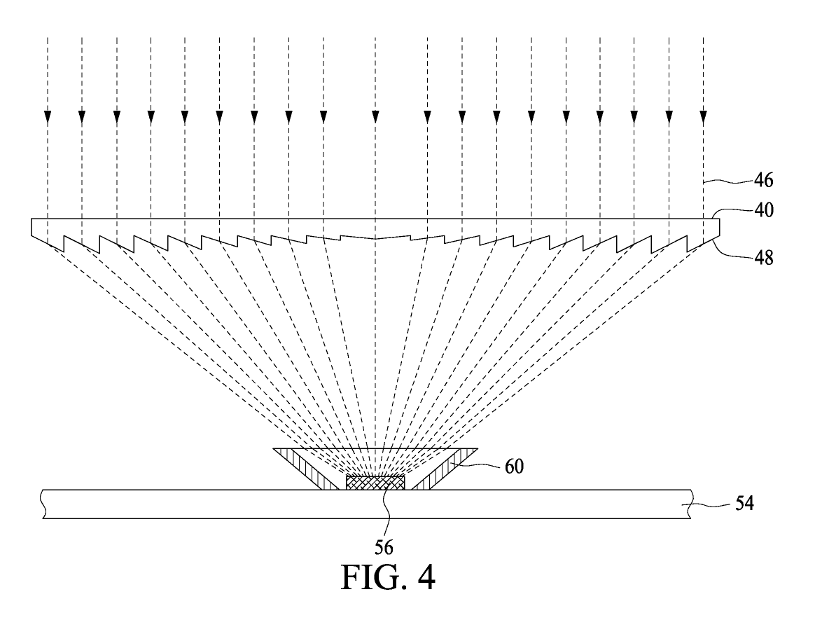

Referring to FIG. 3, the solar cell module 50 comprises a dielectric substrate 54 preferably made of ceramic positioned on the plate 52, a solar cell 56 positioned on an upper surface of the dielectric substrate 54, a protection diode 58 positioned on the upper surface of the dielectric substrate 54, a condenser 60 configured to condense light beams from the Fresnel lens 40 to the solar cell 56, and a heat sink 62 positioned on a bottom surface of the dielectric substrate 54. Preferably, the surface of the supporter 20 is blasted, anodized, or electroplated to increase corrosion resistance. The Fresnel lens 40 includes a plurality of sawtooth-shaped protrusions 48, i.e., the condensing patterns. Light beams passing through the Fresnel lens 40 are focused on the condenser 60 by the Fresnel lens 40 and then condensed on the solar cell 56 by the condenser 60, as shown in FIG. 4.

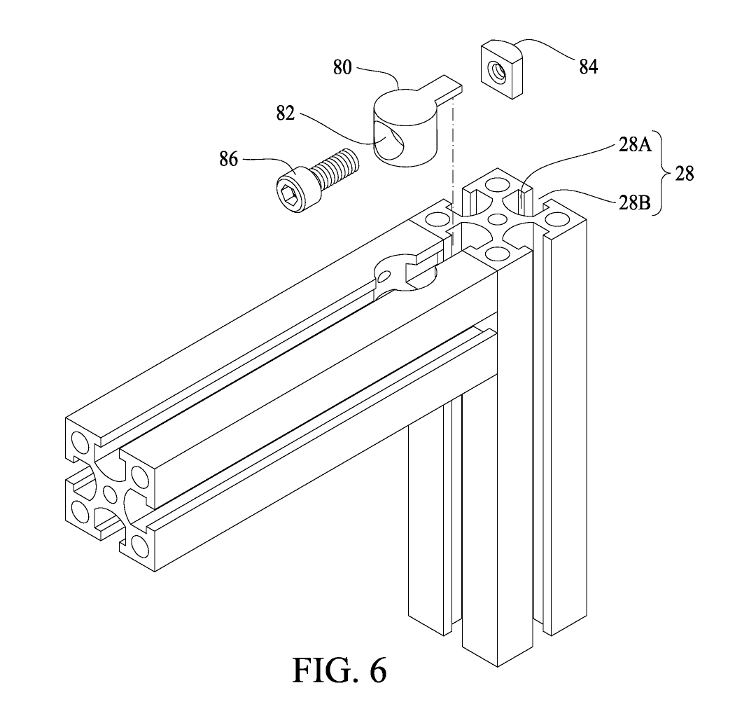

FIG. 5 and FIG. 6 illustrate an assembly of the supporter 20 according to one embodiment of the present invention. In one embodiment of the present invention, the groove 28 is bottle-shaped, i.e., including a bottle portion 28A and a neck portion 28B. The width of the neck portion 28B is smaller than the width of the bottle portion 28A. The supporter 20 may comprise a corner member 70 having a plurality of openings 72 for connecting two perpendicular beams 26, a nut 74 and a spacer 78 positioned in the bottle portion 28A of the groove 28 of the beam 26, and a bolt 76 capable of fixing the corner member 70 on the beam 26, wherein the two perpendicular beams 26 can be assembled by the screwing of the bolt 76 and the nut 74 via the opening 72 of the corner member 70. Preferably, the nut 74 is positioned in the groove 28 together with a spacer 72. In addition, the supporter 20 may comprise a nut 84 positioned in the bottle portion 28A of the groove 28 of a first beam 26, a fixture 80 having an opening 82 positioned in the groove 28 of a second beam 26 perpendicular to the first beam 26, and a bolt 86 capable of fixing the first beam 26 and the second beam 26 wherein the first beam 26 and the second beam 26 can be assembled by the screwing of the bolt 86 and the nut 84 via the opening 82 of the fixture 80.

The prior art uses frames made of glass, which is to heavy to be assembled conveniently and lacks flexibility for changes in design. Conversely, the present supporter is preferably made of aluminum or aluminum-containing alloy and the beam includes at least one hollow interior, and therefore can decrease the weight of the photovoltaic concentrating apparatus dramatically. In addition, the beam of the supporter is grooved, which allows the Fresnel lens and the solar cell module to be assembled at a random position on the beam, and therefore a designer or user can randomly change the number and position of the Fresnel lens and the solar cell module, i.e. the present photovoltaic concentrating apparatus possesses flexibility for changing architecture randomly.

The above-described embodiments of the present invention are intended to be illustrative only. Numerous alternative embodiments may be devised by those skilled in the art without departing from the scope of the following claims.

We claim:

1. A photovoltaic concentrating apparatus, comprising:
a supporter including a plurality of beams, each beam having four side surfaces and four grooves positioned on the four side surfaces, and the grooves being symmetric along a central line of the beam, the beams forming an upper frame and a bottom frame, the beams connecting the upper frame and the bottom frame; and
at least one collecting unit including:
a Fresnel lens positioned on the upper frame of the supporter via a loading frame; and
a solar cell module positioned on the bottom frame of the supporter via a plate.

2. The photovoltaic concentrating apparatus according to claim 1, wherein the grooves have the same cross-section.

3. The photovoltaic concentrating apparatus according to claim 1, wherein the beam includes four corner holes.

4. The photovoltaic concentrating apparatus according to claim 3, wherein the corner holes have the same cross-section.

5. The photovoltaic concentrating apparatus according to claim 3, wherein the corner holes are symmetric along the central line.

6. The photovoltaic concentrating apparatus according to claim 3, wherein each groove is sandwiched between two corner holes.

7. The photovoltaic concentrating apparatus according to claim 3, wherein the beam includes a central hole.

8. The photovoltaic concentrating apparatus according to claim 7, wherein the central hole is disposed among the grooves.

9. The photovoltaic concentrating apparatus according to claim 7, wherein the cross-section of the central hole is different from the cross-section of the corner holes.

10. The photovoltaic concentrating apparatus according to claim 7, wherein the cross-section of the central hole is the same as the cross-section of the corner holes.

11. The photovoltaic concentrating apparatus according to claim 1, wherein the beam includes a central hole.

12. The photovoltaic concentrating apparatus according to claim 11, wherein the central hole is disposed among the grooves.

13. The photovoltaic concentrating apparatus according to claim 1, wherein the grooves is bottle-shaped.

14. The photovoltaic concentrating apparatus according to claim 1, wherein each of the grooves includes a bottle portion and a neck portion, and the width of the neck portion is smaller than the width of the bottle portion.

15. The photovoltaic concentrating apparatus according to claim 14, further includes a nut positioned in the bottle portion.

16. The photovoltaic concentrating apparatus according to claim 1, wherein the loading frame comprises a wing that can be inserted into the groove of the beam.

17. The photovoltaic concentrating apparatus according to claim 1, wherein the solar cell module comprises:
a dielectric substrate positioned on the plate;
a solar cell positioned on the dielectric substrate;
a protection diode positioned on the dielectric substrate;
a condenser configured to condense light beams from the Fresnel lens to the solar cell; and
a heat sink positioned on the dielectric substrate.

18. The photovoltaic concentrating apparatus according to claim 1, wherein the beam includes at least one hollow interior.

19. The photovoltaic concentrating apparatus according to claim 1, wherein the supporter comprises:
a corner member having a plurality of openings for connecting two perpendicular beams;
a nut positioned in the groove of the beam; and
a bolt in association with the nut through the opening for fixing the corner member onto the beam.

20. The photovoltaic concentrating apparatus according to claim 1, wherein the supporter comprises:
a nut positioned in a first beam;
a fixture having an opening positioned in a second beam perpendicular to the first beam; and
a bolt in association with the nut through the opening for fixing the first beam and the second beam.
